(19) United States
(12) Patent Application Publication
(10) Pub. No.: US 2007/0176160 A1
(43) Pub. Date: Aug. 2, 2007

(54) Electron tube

(75) Inventors: Shoichi Uchiyama, Hamamatsu-shi (JP); Yasufumi Takagi, Hamamatsu-shi (JP); Harumasa Yoshida, Hamamatsu-shi (JP)

Correspondence Address: DRINKER BIDDLE & REATH (DC), 1500 K STREET, N.W., SUITE 1100, WASHINGTON, DC, 20005-1209, US

(73) Assignee: HAMAMATSU PHOTONICS K.K.

(21) Appl. No.: 11/340,849

(22) Filed: Jan. 27, 2006

(51) Int. Cl. H01L 29/06

(52) U.S. Cl. 257/10

(57) ABSTRACT

A GaN-based semiconductor photocathode is applied to an electron tube. A GaN-based compound semiconductor layer is laterally grown on a substrate, and incorporated in the electron tube. The crystal defects of the compound semiconductor layer are reduced, whereby an electron tube which has inconceivably high sensitivity is realized.

### BACKGROUND OF THE INVENTION

1. Field of the Invention

The present invention relates to an electron tube.

2. Related Background of the Invention

Conventionally, a PIN-photodiode formed by growing a GaN layer on a sapphire substrate is generally known (Japanese Published Unexamined Patent Application No. 2002-208722). In addition, a technique to form a laser diode on a GaN layer grown on a GaN substrate is also known (Japanese Published Unexamined Patent Application No. 2000-244061). In a reflecting type GaN photocathode, the relationship between the Mg doping amount and sensitivity has been studied (F. S. Shahedipour, et. al. IEEE J. Quantum Electron., 38, 333 (2002)).

### SUMMARY OF THE INVENTION

However, such a compound semiconductor has not been applied to a semiconductor photocathode due to its many crystal defects although it has been known as a material of a photodiode or laser diode. In conventional semiconductor photocathodes, GaAs and the like are used, and the sensitivity in the ultraviolet range of an electron tube using this is not sufficient. Therefore, the inventors of this invention applied a GaN-based compound semiconductor to a semiconductor photocathode of an electron tube and reduced the crystal defects, whereby they invented an electron tube that had a high sensitivity that is conventionally inconceivable. In the electron tube of the invention, a GaN-based compound semiconductor layer was laterally grown on a substrate, and incorporated as a semiconductor photocathode in the electron tube.

### BRIEF DESCRIPTION OF THE DRAWINGS

FIG. 1 is a longitudinal sectional view of a first photocathode main body to be applied to an electron tube;

FIG. 2A, FIG. 2B, FIG. 2C, FIG. 2D, and FIG. 2E are drawings for explaining a method for manufacturing a photocathode;

FIG. 3 is a longitudinal sectional view of a second photocathode main body to be applied to an electron-tube;

FIG. 4 is a longitudinal sectional view of a third photocathode main body to be applied to an electron tube;

FIG. 5 is a longitudinal sectional view of a fourth photocathode main body to be applied to an electron tube;

FIG. 6 is a longitudinal sectional view of a fifth photocathode main body to be applied to an electron tube;

FIG. 7A, FIG. 7B, FIG. 7C, FIG. 7D, and FIG. 7E are drawings for explaining a method for manufacturing a photocathode;

FIG. 8 is a longitudinal sectional view of a sixth photocathode main body to be applied to an electron tube;

FIG. 9 is a longitudinal sectional view of a seventh photocathode main body to be applied to an electron tube;

FIG. 10 is a longitudinal sectional view of an eighth photocathode main body to be applied to an electron tube;

FIG. 11 is a longitudinal sectional view of a ninth photocathode main body to be applied to an electron tube;

FIG. 12 is a longitudinal sectional view of a tenth photocathode main body to be applied to an electron tube;

FIG. 13 is a longitudinal sectional view of an eleventh photocathode main body to be applied to an electron tube;

FIG. 14 is a longitudinal sectional view of a twelfth photocathode main body to be applied to an electron tube;

FIG. 15 is a graph showing the relationship between wavelength (nm) and quantum efficiency (%);

FIG. 16 is a graph showing the relationship between wavelength (nm) and quantum efficiency (%) when electron escape probability is changed;

FIG. 17 is a graph showing the relationship between wavelength (nm) and quantum efficiency (%) when the diffusion length is changed;

FIG. 18 is a graph showing the relationship between dislocation density (cm⁻²) and quantum efficiency (%);

FIG. 19 is a graph showing the relationship between dislocation density (cm⁻²) and minority electron diffusion length (nm);

FIG. 20A is a cross sectional view of a side-on type photo multiplier (electron tube);

FIG. 20B is a longitudinal sectional view of a photocathode to be applied to the electron tube of FIG. 19A;

FIG. 21A is a longitudinal sectional view of an image intensifier (electron tube);

FIG. 21B is a longitudinal sectional view of a photocathode to be applied to the electron tube of FIG. 21A;

FIG. 22 is a perspective view of a photoelectric tube (electron tube) using a photocathode main body; and

FIG. 23 is a graph showing the relationship between activation time and relative quantum yield (a.u.).

### DESCRIPTION OF THE PREFERRED EMBODIMENTS

Hereinafter, an electron tube relating to an embodiment is described. The same symbol is used for components identical to each other, and overlapping description is omitted.

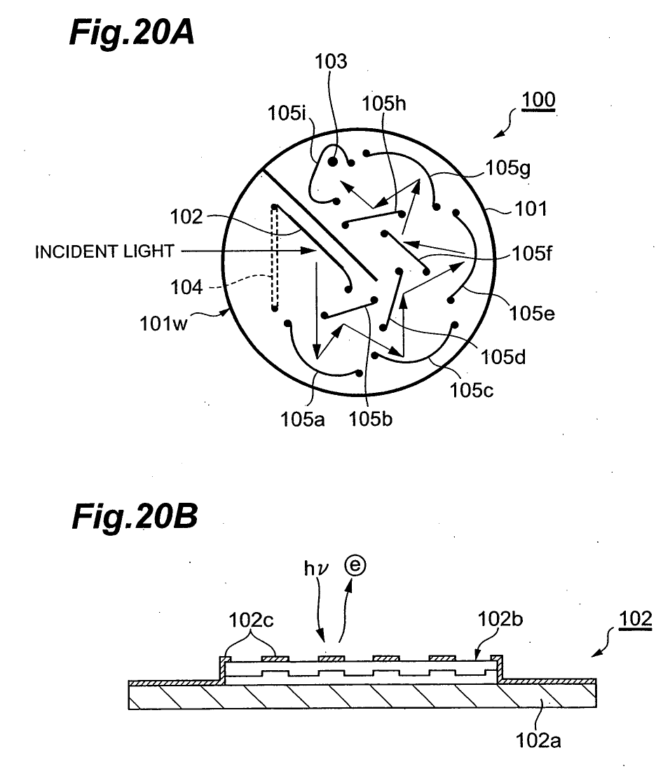

FIG. 20A is a cross sectional view of a side-on type photo multiplier (electron tube) 100.

The electron tube 100 comprises a vacuum container 101, a photocathode 102, and an anode 103. The vacuum container 101 is made of a glass bulb that provides an environment with an extra-low pressure inside, and its side wall forms an entrance window 101w. Light entering the inside of the vacuum container 101 via the entrance window 101w penetrates a mesh grid 104 and enters the photocathode 102. This photocathode 102 is a reflecting type photocathode, and emits photoelectrons in vacuum according to light entering.

Photoelectrons that have exited from the photocathode 102 enter a plurality of dynodes 105a, 105b, 105c, 105d, 105e, 105f, 105g, 105h, and 105i in order, and are finally collected by the anode 103. Namely, the anode 103 is disposed inside the vacuum container 101, and collects electrons emitted from the photocathode 102.

FIG. 20B is a longitudinal sectional view of the photocathode 102 to be applied to the electron tube of FIG. 20A.

The photocathode 102 is formed by attaching a photocathode main body 102b onto a metal plate 102a. The photocathode main body 102b has a mesh-like electrode 102c on the exposed surface, and the electrode 102c is electrically connected to the metal plate 102a. The photocathode 102 emits photoelectrons e in reverse to the light entering direction according to entering of light (hγ) of infrared rays or the like.

Electron tubes other than the photo multiplier are also known.

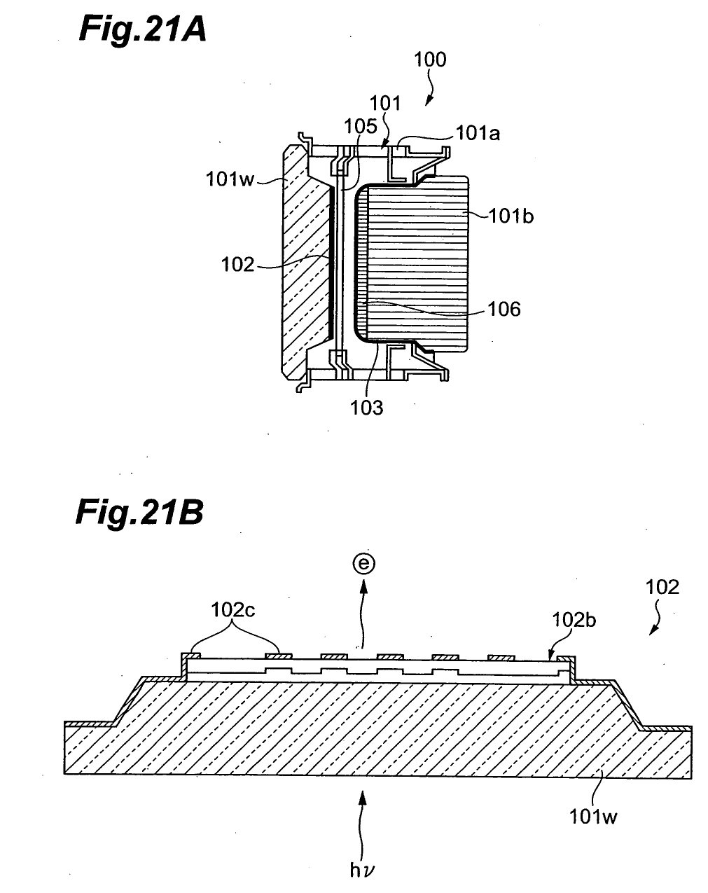

FIG. 21A is a longitudinal sectional view of an image intensifier (electron tube).

The electron tube 100 comprises a vacuum container 101, a photocathode 102, and an anode 103. The vacuum container 101 includes a cylindrical ceramic side tube 101a that provides an environment with an extra-low pressure inside, a glass-made entrance window 101w that closes an opening on one side of the ceramic side tube 101a, and a glass-made exit window 101b that closes an opening on the other side of the ceramic side tube 101a. Light entering the inside of the vacuum container 101 via the entrance window 101w enters the photocathode 102 attached to the inner surface of the entrance window 101w. The photocathode 102 is a transmitting photocathode, and emits photoelectrons in vacuum according to light entering.

Photoelectrons that have exited from the photocathode 102 enter an electronic amplifying part (micro channel plate: MCP) 105 and are amplified, and then collected by the anode 103. Namely, the anode 103 is disposed inside the vacuum container 101 and collects electrons emitted from the photocathode 102.

The anode 103 is formed on the inner surface of the exit window 101b, and the exit window 101b is formed of an optical fiber plate. An optical image that has entered the photocathode 102 is converted into an electron image by the photocathode 102, multiplied by a photo multiplying part 105, and then enters the anode 103. The anode 103 is in contact with a fluorescent material 106, and the fluorescent material 106 emits light according to the entering electron image. The fluorescent image generated by the fluorescent material 106 is outputted to the outside of the image intensifier via the exit window 101b. The exit window 101b is formed of an optical fiber plate formed by bundling optical fibers in parallel to the tube axis.

FIG. 21B is a longitudinal sectional view of a photocathode to be applied to the electron tube of FIG. 21A.

The photocathode 102 is formed by attaching a photocathode main body 102b onto the inner surface of the insulating entrance window 101w. The photocathode main body 102b has a mesh-like electrode 102c on the exposed surface, and the electrode 102c is electrically connected to a ceramic side tube 101a by trailing on the inner surface of the entrance window 101w. The photocathode 102 emits photoelectrons e in the same direction as the light entering direction according to entering of light (hγ) of infrared rays or the like.

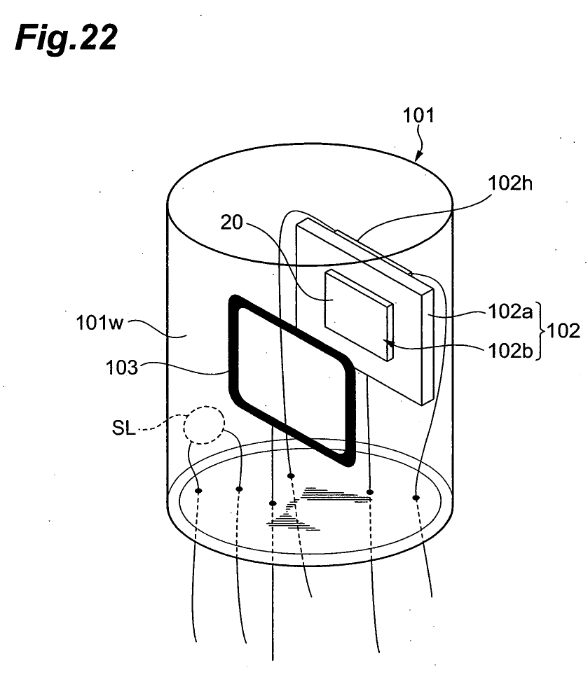

FIG. 22 is a perspective view of a photoelectric tube (electron tube) using a photocathode main body.

When a photoelectric tube (electron tube) is formed by using the above-described photocathode main body, the photocathode main body (GaN crystal) 102b is cleaved into a size of 8 mm×8 mm and then organically cleaned and fixed onto the metal plate 102a, whereby forming a photocathode. The anode 103 is an Ni-made ring, and is fixed at a 4 mm distance from the photocathode main body 102b so as to face the photocathode main body, and collects photoelectrons emitted from the reflecting type photocathode 102. The vacuum container 101 forming the photoelectric tube has an outside diameter of 1 to ½ inches, and is made of sapphire. A part of this vacuum container 101 forms the entrance window 101w. A heater 102h for GaN crystal cleaning was attached to the back side of the metal plate 102a to which GaN crystals have been fixed, and an Ni-made sleeve SL including Cs chromate was also attached as an alkali material to the inside of the vacuum container 101. The sectional view of the photocathode is similar to that of FIG. 20B, and all the electron tubes described above include a sleeve containing an alkali material inside the vacuum containers.

The exposed surface of the photocathode main body 102b is activated by the alkali metal (Cs).

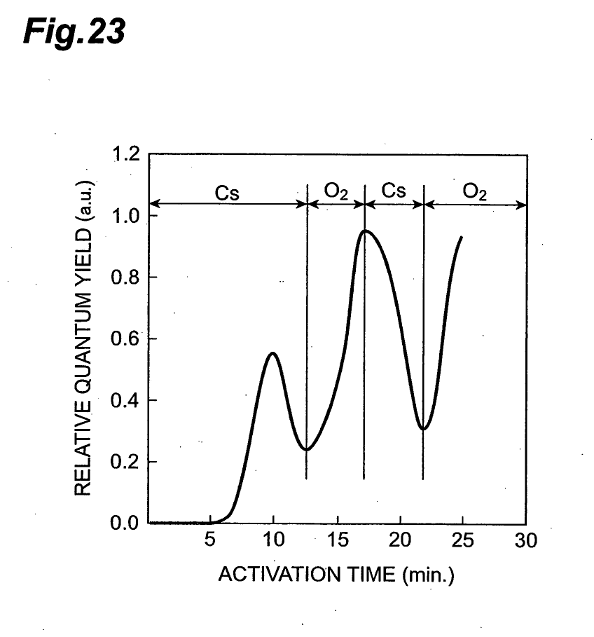

FIG. 23 is a graph showing the relationship between activation time and relative quantum yield (a.u.).

To form the alkali metal layer 20 on the exposed surface of the photocathode main body 102b, the sleeve SL is energized for heating, and then oxygen is supplied to the inside of the vacuum container 101 to oxidize the alkali metal. The alkali metal supply to the exposed surface and the oxygen supply are alternately performed.

In this activation process, while the exposed surface of the photocathode main body 102b was irradiated with ultraviolet rays by a low-pressure mercury lamp, the current flowing in the anode 103 was monitored. When the alkali metal (Cs) is continuously supplied, the current (relative quantum efficiency) gradually increases. Thereafter, the current reaches a peak and then becomes minimum. When the current reaches a minimum, the alkali metal supply is stopped, and oxygen is supplied instead.

This oxygen is supplied by heating of a heater wound around a silver-made tube attached to the exhauster. When supplying oxygen, the current gradually increases. When the current becomes maximum, heating of the silver tube is stopped, and then the alkali metal (Cs) is supplied again. The supply of the alkali metal (Cs) is continued until the current reaches a minimum.

This set of alkali metal supply and oxygen supply is repeated twice.

After finishing activation, the glass tube connecting the electron tube and the exhauster is fused by a burner and cut away.

Hereinafter, a photocathode main body 102b to be applied to the above-described electron tube is explained.

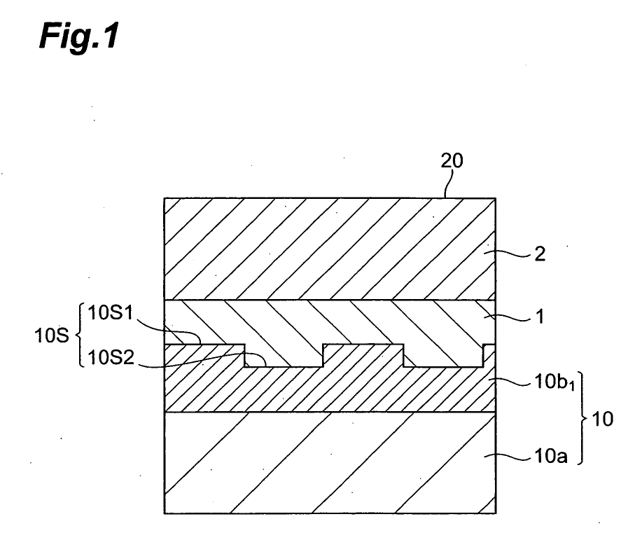

FIG. 1 is a longitudinal sectional view of a first photocathode main body to be applied to the electron tube.

This photocathode main body comprises a substrate 10 having an uneven surface 10S, a first nitride compound semiconductor layer 1 grown inside depressions 10S1 and on projections 10S2 of the uneven surface 10S of the substrate 10, and a-second nitride compound semiconductor layer 2 that is grown on the first nitride compound semiconductor layer 1 and has an impurity concentration higher than that of the first nitride compound semiconductor layer 1.

Herein, the substrate 10 includes a base substrate 10a, and a foundation nitride compound semiconductor layer 10b₁ that is formed on the base substrate 10a and has the uneven surface 10S.

In the photocathode main body, the electrode is provided on the exposed surface of the second nitride compound semiconductor layer 2. In addition, on the exposed surface of the second nitride compound semiconductor layer 2, the above-described oxidized alkali metal layer (CsO) 20 is provided to lower the work function as appropriate. The alkali metal is Li, Na, K, Rb, or Cs or the like.

In this example, the base substrate 10a is made of sapphire, the foundation nitride compound semiconductor layer 10b₁ is made of GaN, and the first nitride compound semiconductor layer 1 and the second nitride compound semiconductor layer 2 are both made of GaN. The foundation nitride compound semiconductor layer 10b₁ and the first nitride compound semiconductor layer 1 are not added (undoped) with impurities, and the second nitride compound semiconductor layer 2 is doped with Mg. The Mg impurity concentration in the semiconductor nitride compound semiconductor layer 2 is 4×10¹⁸ to 3×10²⁰ cm⁻³.

According to the electron tube using this photocathode, the first nitride compound semiconductor layer 1 is laterally grown on the substrate 10 having an uneven surface, and then, the second nitride compound semiconductor layer 2 with an impurity (Mg doped) concentration higher than that of the first nitride compound semiconductor layer 1 is grown on the first nitride compound semiconductor layer 1, so that the dislocation density in the crystals can be remarkably reduced. The dislocation densities in the first and second nitride compound semiconductor layers 1 and 2 are reduced although the dislocation defect remains on the substrate 10 side. When the dislocation density in the crystals is reduced, the quantum efficiency is improved. Particularly, it was found that the quantum efficiency in the case where an ultraviolet ray of 200 nm to 400 nm entered the photocathode reached twice the quantum efficiency of the photocathode that did not include the substrate with an uneven surface. The foundation nitride compound semiconductor layer 10b₁ and the first and second nitride compound semiconductor layers 1 and 2 are all made of GaN, so that these have sensitivities for ultraviolet rays, and lattice mismatch among these is reduced.

Next, a method for manufacturing the photocathode main body of FIG. 1 is explained.

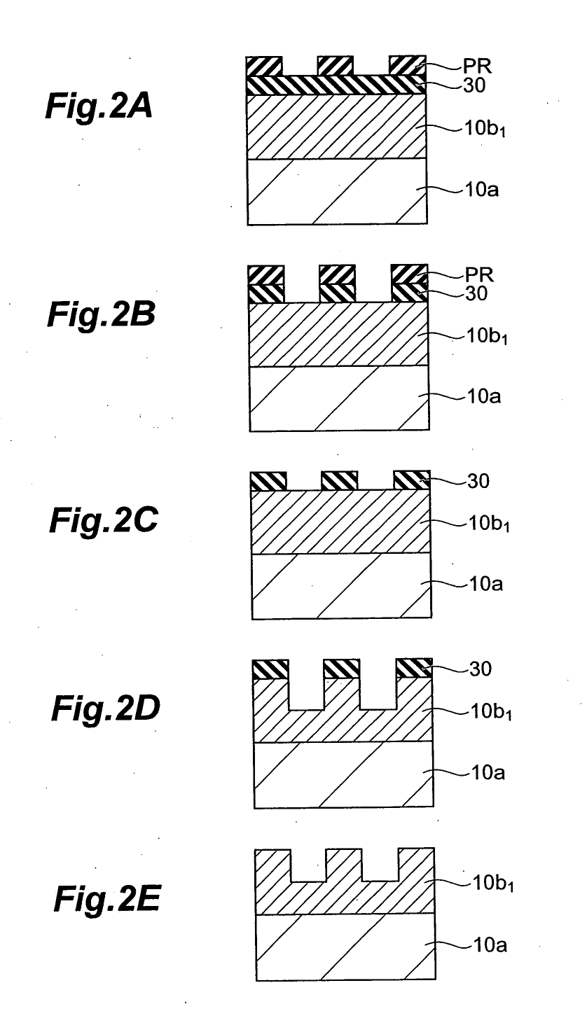

FIG. 2A, FIG. 2B, FIG. 2C, FIG. 2D, and FIG. 2E are drawings for explaining the method for manufacturing the photocathode main body 10 of FIG. 1.

For crystal growth described below, metalorganic chemical vapor deposition (MOCVD) was used. As a Ga material, trimethyl gallium (TMGa) was used, and as an N material, ammonia (NH₃) was used. As a carrier gas, hydrogen and nitrogen were used.

For the base substrate 10a, sapphire (0001) was used. First, the base substrate 10a is introduced into an MOCVD growth system, and then subjected to heat treatment for 5 minutes at 1050° C. in a hydrogen atmosphere to clean the substrate surface.

Thereafter, the substrate is raised in temperature to 1075° C. and the foundation nitride compound semiconductor layer 10b₁ (GaN) is grown to approximately 4 μm on the base substrate 10a. The growing pressure was set to a normal pressure (1×10⁵ Pa), the TMGa feed rate was set to 92 μmol/min, and the NH₃ feed rate was set to 8 SLM.

In this example, metalorganic chemical vapor deposition (MOCVD) was used for crystal growth, however, the invention is not limited to this, and molecular beam epitaxy (MBE), hydride vapor phase epitaxy (HVPE), or the like can also be used.

Next, to perform unevenness processing, the substrate including the nitride compound semiconductor layer 10b₁ grown on sapphire (0001) was taken out of the growth system and introduced into a plasma CVD system, and a mask 30 made of SiO₂ is deposited to 300 nm on the nitride compound semiconductor layer 10b₁. The deposition conditions were set to a temperature of 400° C., a pressure of 93 Pa, a silane (SiH₄) flow rate of 10 SCCM, a nitrous oxide (N₂O) feed rate of 350 SCCM, and an argon (Ar) flow rate of 180 SCCM.

In this example, plasma CVD was used for deposition of the mask 30, however, the invention is not limited to this, and electron beam (EB) deposition, sputtering, or the like can also be used.

After deposition of the mask 30, a photoresist mask PR patterned into periodic stripes is formed on the mask 30 by means of photolithography. The lengthwise direction of the stripes is the [11-20] direction of the sapphire substrate ([1-100] direction of the GaN crystal). The width of the stripes is 14 μm, and the period is 28 μm (FIG. 2A).

Next the mask 30 is patterned. By using the photoresist PR patterned into periodic stripes as a sub mask, the mask 30 is etched by means of reactive ion etching (RIE). As etching conditions, an RF power is set to 150 W, a pressure is set to 5.3 Pa, a CF₄ flow rate is set to 45 SCCM, and an oxygen (O₂) flow rate is set to 5 SCCM, and etching is performed until reaching the surface of the foundation nitride compound semiconductor layer 10b₁ (FIG. 2B).

Thereafter, the photoresist PR used as a sub mask was removed by an organic solvent and oxygen plasma treatment, whereby a periodic stripe pattern of the mask 30 was formed (FIG. 2C).

In this example, reactive ion etching was used for SiO₂ etching, however, the invention is not limited to this, and a fluoride-based solution such as buffered hydrogen fluoride (BHF) can also be used.

Next, the foundation nitride compound semiconductor layer 10b₁ is etched. The foundation nitride compound semiconductor layer 10b₁ is reactive-ion-etched (RIE) via the mask 30 having the periodic stripe pattern. As etching conditions an RF power of 280 W, a pressure of 4 Pa, a chlorine (Cl₂) flow rate of 20 SCCM, and a silicon tetrachloride (SiCl₄) flow rate of 5 SCCM are set, and the foundation nitride compound semiconductor layer 10b₁ is etched to a depth of approximately 2 μm from the surface (FIG. 2D).

After etching, SiO₂ used as the mask 30 is etched in a buffered hydrogen fluoride solution (FIG. 2E).

In this example, reactive ion etching (RIE) was used for GaN etching, however, the invention is not limited to this, and reactive ion beam etching (RIBE), ICP dry etching, or the like can be used.

After the substrate is formed as described above, the first nitride compound semiconductor layer 1 and the second nitride compound semiconductor layer 2 are grown.

First, the first nitride compound semiconductor layer (GaN) 1 shown in FIG. 1 is laterally embedded and grown. The substrate 10 subjected to unevenness processing is introduced into the MOCVD growth system again, and subjected to heat treatment for 5 minutes at 1075° C. in a hydrogen and ammonia atmosphere to clean the substrate surface.

After cleaning the substrate surface, GaN is laterally embedded and grown at a substrate temperature of 1125° C. The grown film thickness corresponds to approximately 11 μm in the case of growth on a flat substrate. The growing pressure is 1×1⁴ Pa, the TMGa feed rate is 92 μmol/min, and the NH₃ feed rate is 3 SLM.

Thereafter, the second nitride compound semiconductor layer (GaN) 2 doped with magnesium (Mg) to become a light absorbing layer and an electron emitting layer of the photocathode is grown to approximately 2.5 μm on the first nitride compound semiconductor layer 1. The growing pressure is a normal pressure (1×10⁵ Pa), the growing temperature is 1075° C., the TMGa feed rate is 92 μmol/min, and the NH₃ feed rate is 8 SLM. As the Mg material, Bis (cyclopentadienyl) magnesium (Cp₂Mg) was used, and the Mg concentration was set to 3×19¹⁹ cm⁻³.

The photocathode main body shown in FIG. 1 is thus completed. After the photocathode main body is disposed inside the vacuum container, the alkali layer 20 is formed on the exposed surface of the second nitride compound semiconductor layer 2, whereby the photocathode is completed.

The stripe period and depth can be arbitrarily set in certain ranges. In the crystal structure, doping and film thickness are not always limited except that the second nitride compound semiconductor layer 2 that becomes the uppermost light absorbing and electron emitting layer is doped with Mg. This Mg doping concentration is preferably 3×10¹⁹ cm⁻³, however, it is not limited to this.

The crystal growing method and conditions and the process method and conditions shown in this example are only one example, and these are not limited as long as the target crystal growth and process are possible. In the unevenness processing shown in this example, GaN etching by using the SiO₂ mask is shown, however, the invention is not limited to this, and GaN etching by using a resist or Ni as a mask is also possible.

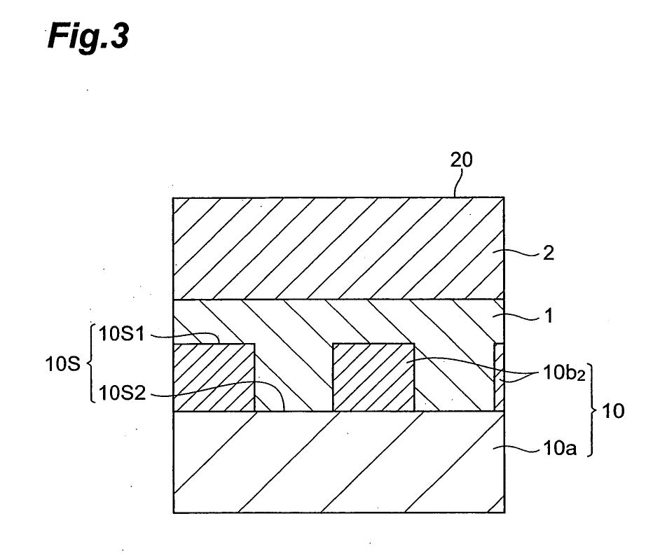

FIG. 3 is a longitudinal sectional view of the second photocathode main body to be applied to an, electron tube.

This photocathode main body is different from the first photocathode main body in the construction of the substrate 10. The substrate 10 comprises a base substrate 10a and a foundation nitride compound semiconductor layer 10b₂ that is formed on the base substrate 10a and forms uneven surface 10S in conjunction with the exposed surface of the base substrate 10a.

In this example, the base substrate 10a is made of sapphire, the foundation nitride compound semiconductor layer 10b₂ is made of GaN, and the first nitride compound semiconductor layer 1 and the second nitride compound semiconductor layer 2 are both made of GaN. This method for manufacturing the photocathode main body is different in etching to be performed until the surface of the base substrate 10a is exposed in the process of FIG. 2D, and other processes are the same as described above.

Namely, in place of the foundation nitride semiconductor layer 10bᵢ, the foundation nitride semiconductor layer 10b₂ is formed on the base substrate 10a, and then the mask 30 and the photoresist pattern PR are formed on this foundation nitride semiconductor layer, and the foundation nitride semiconductor layer (GaN) 10b₂ is reactive-ion-etched (RIE) via the mask 3 having a periodic stripe pattern. As etching conditions, an RF power of 280 W, a pressure of 4.0 Pa, a chlorine (Cl₂) flow rate of 20 SCCM, and a silicon tetrachloride (SiCl₄) flow rate of 5 SCCM are set, and the foundation nitride semiconductor layer 10b₂ is etched by approximately 4 μm from the surface so as to reach the base substrate 10a. There is no problem with etching of the base substrate 10a together. After etching, in a buffered hydrogen fluoride (BHF) solution, SiO₂ used as the mask 30 is etched.

The residual process is the same as that of FIG. 1, and the photocathode main body is thus completed. After disposing of the photocathode main body in the vacuum container, an alkali layer 20 is formed on the exposed surface of the second nitride compound semiconductor layer 2, whereby a photocathode is completed. In this example, the same effect as described above is also obtained.

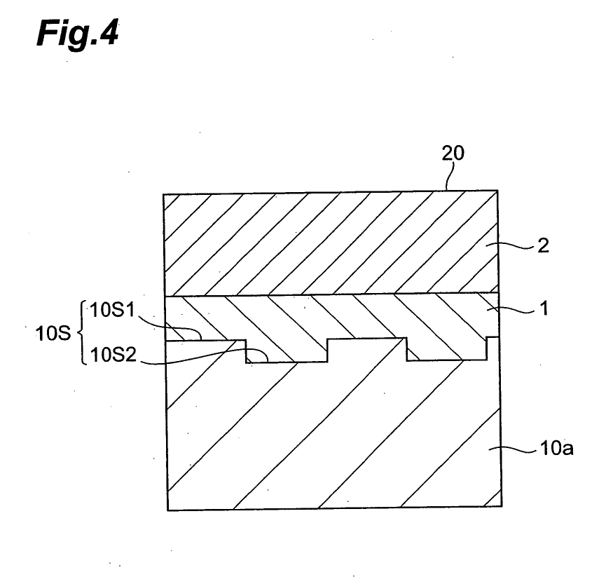

FIG. 4 is a longitudinal sectional view of the third photocathode main body to be applied to an electron tube.

This photocathode main body is different from the first photocathode main body in the construction of the substrate 10. The substrate 10 is made of a single material, and consists of only the base substrate 10a having an uneven surface 10S.

In this example, the base substrate 10a is made of sapphire, and the first nitride compound semiconductor layer 1 and the second nitride compound semiconductor layer 2 are both made of GaN. In this example, the same effect as described above is also obtained.

A method for manufacturing this photocathode main body is explained.

First, on the base substrate 10a made of sapphire, a stripe mask made of Ni is formed by liftoff technology. This stripe direction is the [11-20] direction of the sapphire substrate ([1-100] direction of GaN crystal). The stripe width is 14 μm, and the period is 28 μm. It is also possible that the stripe mask is formed by wet etching or dry etching by using nitric acid or the like.

Next, the base substrate 10a made of sapphire is reactive-ion-etched (RIE) by using a chlorine-based gas via the stripe mask having the formed stripe pattern. After etching, Ni used as a mask is etched in a nitric acid solution.

In this example, reactive ion etching (RIE) was used for etching sapphire, however, the invention is not limited to this, and reactive ion beam etching (RIBE), ICP dry etching, or the like can be used. As the mask, Ni was used, however, the invention is not limited to this.

Thereafter, the first nitride compound semiconductor layer (GaN) 1 is embedded and grown. For crystal growth, metalorganic chemical vapor deposition (MOCVD) was used. As a Ga material, trimethyl gallium (TMGa) was used, and as an N material, ammonia (NH₃) was used. As a carrier gas, hydrogen and nitrogen were used.

On the base substrate 10a of sapphire (0001) subjected to the above-described etching, a first nitride compound semiconductor layer (GaN) 1 is formed. The base substrate 10a is introduced into an MOCVD growth system and then subjected to heat treatment for 5 minutes at 1050° C. in a hydrogen atmosphere to clean the substrate surface.

Thereafter, the first nitride compound semiconductor layer (GaN) 1 is laterally embedded and grown at a substrate temperature of 1125° C. The growing pressure is 1×10⁴ Pa, the TMGa feed rate is 92 μmol/min, and the NH₃ feed rate is 3 SLM.

Thereafter, the second nitride compound semiconductor layer (GaN) 2 doped with magnesium (Mg) to become the light absorbing layer and the electron emitting layer of the photoelectric surface is grown to a thickness of approximately 2.5 μm on the first nitride compound semiconductor layer 1. The growing pressure is a normal pressure (1×10⁵ Pa), the growing temperature is 1075° C., the TMGa feed rate is 92 μmol/min, and the NH₃ feed rate is 8 SLM. As the Mg material, Bis (cyclopentadienyl) magnesium (Cp₂Mg) was used, and the Mg concentration was set to 3×10¹⁹ cm⁻³.

The photocathode main body is thus completed. After disposing of the photocathode main body in the vacuum container, an alkali layer 20 is formed on the exposed surface of the second nitride compound semiconductor layer 2, whereby a photocathode is completed.

In this example, metalorganic chemical vapor deposition (MOCVD) was used for crystal growth, however, the invention is not limited to this, and molecular beam epitaxy (MBE), hydride vapor phase epitaxy (HVPE), or the like can also be used.

In addition, the stripe period and depth can be arbitrarily set in certain ranges. Concerning the crystal structure, the doping and film thickness are not always limited except that the uppermost light absorbing and electron emitting layer is doped with Mg. The Mg doping concentration is preferably 3×10¹⁹ cm⁻³, however, it is not limited to this.

The crystal growing method and conditions and the process method and conditions shown in this example are only one example, and these are not limited as long as the target crystal growth and process are possible.

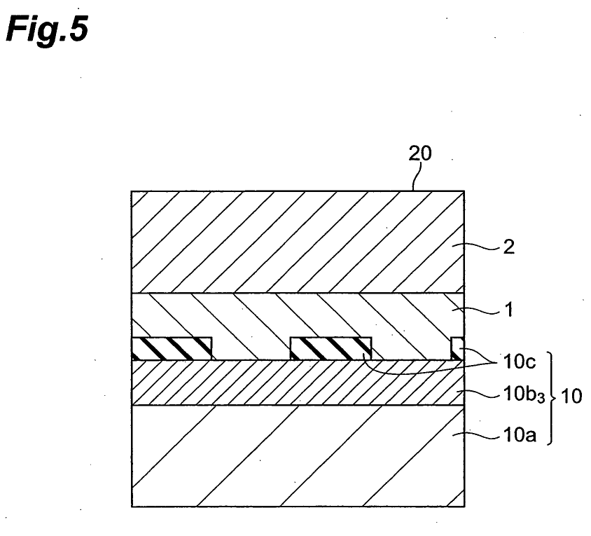

FIG. 5 is a longitudinal sectional view of the fourth photocathode main body to be applied to an electron tube.

This photocathode main body is different from the first photocathode main body in the construction of the substrate 10.

The substrate 10 comprises a base substrate 10a, a foundation nitride compound semiconductor layer 10b₃ formed on the base substrate 10a, and a stripe mask layer 10c formed on the foundation nitride compound semiconductor layer 10b₃, and the surface of the mask layer 10c forms an uneven surface 10S in conjunction with the exposed surface of the foundation nitride compound semiconductor layer 10b₃.

In this example, the base substrate 10a is made of sapphire, the foundation nitride compound semiconductor layer 10b₃ is made of GaN, the mask layer 10c is made of SiO₂, and the first nitride compound semiconductor layer 1 and the second nitride compound semiconductor layer 2 are both made of GaN. In this example, the same effect as described above can also be obtained.

A method for manufacturing the photocathode main body is described.

For crystal growth, metalorganic chemical vapor deposition (MOCVD) was used. As a Ga material, trimethyl gallium (TMGa) was used, and as an N material, ammonia (NH₃) was used. As a carrier gas, hydrogen and nitrogen were used.

For the base substrate a, sapphire (0001) was used. The base substrate 10a is introduced into an MOCVD growth system and then subjected to heat treatment for 5 minutes at 1050° C. to clean the substrate surface. Then, the substrate is raised in temperature to 1075° C., and the foundation nitride compound semiconductor layer (GaN) 10b₃ is grown to approximately 4 μm. The growing pressure was set to a normal pressure (1×10⁵ Pa), the TMGa feed rate was set to 92 μmol/min, and the NH₃ feed rate was set to 8 SLM.

In this example, for crystal growth, metalorganic chemical vapor deposition (MOCVD) was used, however, the invention is not limited to this, and molecular beam epitaxy (MBE), hydride vapor phase epitaxy (HVPE), or the like can also be used.

Next, the substrate having the foundation nitride compound semiconductor layer (GaN) 10b₃ formed on sapphire (0001) is taken out of the growth system, and introduced into a plasma CVD system, and a mask layer 10c made of SiO₂ is deposited to 300 nm. As deposition conditions, a temperature of 400° C., a pressure of 93 Pa, a silane (SiH₄) flow rate of 10 SCCM, a nitrous oxide (N₂O) feed rate of 350 SCCM, and an argon (Ar) flow rate of 180 SCCM were set.

In this example, plasma CVD was used for deposition of the SiO₂ film, however, the invention is not limited to this, and electron beam (EB) deposition, sputtering, or the like can also be used.

After depositing the SiO₂ film, a photoresist patterned into periodic stripes is formed on the mask layer 10c (before being etched) by means of photolithography. The stripe direction is the [11-20] direction of the sapphire substrate ([1-100] direction of the GaN crystal). The stripe width is 4 μm, and the period is 14 μm.

The mask layer 10c is etched by means of reactive ion etching (RIE) by using the photoresist patterned into periodic stripes as a mask. As etching conditions, an RF power of 150 W, a pressure of 5.3 Pa, a CF₄ flow rate of 45 SCCM, and an oxygen (O₂) flow rate of 5 SCCM are set and etching is performed until reaching the surface of the foundation nitride compound semiconductor layer 10b₂. Thereafter, the resist used as a mask was removed by an organic solvent and oxygen plasma treatment to form a mask layer 10c that was made of SiO₂ and had a periodic stripe pattern was formed.

In this example, reactive ion etching was used for etching SiO₂, however, the invention is not limited to this, and a fluoride-based solution such as buffered hydrogen fluoride (BHF) can also be used.

Next, the first nitride compound semiconductor layer 1 is laterally grown. The substrate including the formed SiO₂ stripes is introduced into the MOCVD growth system again, and subjected to heat treatment for 5 minutes at 1075° C. in an ammonia atmosphere to clean the substrate surface. After cleaning the substrate surface, GaN is laterally embedded and grown. The substrate temperature is 1025° C. and the growing pressure is 6.7×10⁴ Pa, and growth is made while forming facets (for example, the [11-22] surface and [11-20] surface). Then, on this compound semiconductor layer, a compound semiconductor layer is further grown at a substrate temperature of 1125° C. and a growing pressure is 1×10⁴ Pa, and growth is continued until the surface becomes flat. The TMGa feed rate in this case is 92 μmol/min, and the NH₃ feed rate is 3 SLM.

Next, a light absorbing and photoelectron emitting layer is grown. The second nitride compound semiconductor layer (GaN) 2 doped with magnesium (Mg) to become a light absorbing layer and an electron emitting layer is grown to approximately 2.5 μm on the first nitride compound semiconductor layer 1. The growing pressure is a normal pressure (1×10⁵ Pa), the growing temperature is 1075° C., the TMGa feed rate is 92 μmol/min, and the NH₃ feed rate is 8 SLM. As the Mg material, Bis (cyclopentadienyl) magnesium (Cp₂Mg) was used and the Mg concentration was set to 3×10¹⁹ cm⁻³.

The photocathode main body is thus completed. After disposing of the photocathode main body in the vacuum container, an alkali layer 20 is formed on the exposed surface of the second nitride compound semiconductor layer 2, whereby a photocathode is completed.

The stripe period can be arbitrarily set in a certain range. Concerning the crystal structure, the doping and film thickness are not always limited except that the uppermost light absorbing and electron emitting layer is doped with Mg. The Mg doping concentration is preferably 3×10¹⁹ cm⁻³, however, it is not limited to this. The crystal growing method and conditions and the process method and conditions shown in this example are only one example, and these are not limited as long as the target crystal growth and process are possible.

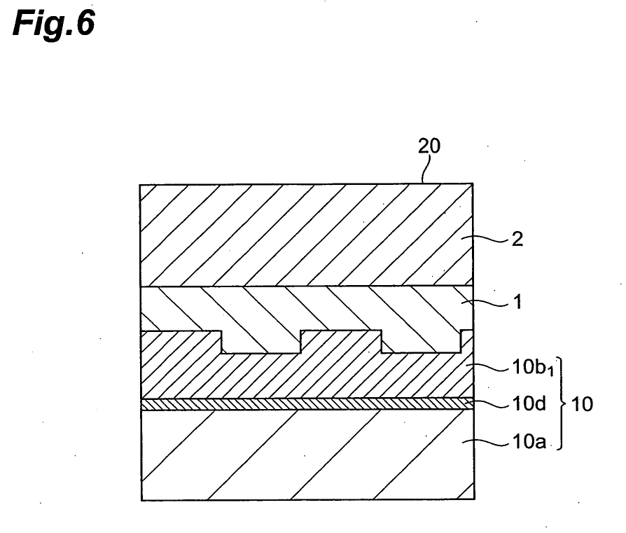

FIG. 6 is a longitudinal sectional view of the fifth photocathode main body to be applied to an electron tube.

This photocathode main body further comprises, in addition to the photocathode main body of FIG. 1, a buffer layer 10d interposed between the base substrate 10a and the foundation nitride compound semiconductor layer 10b₁. The buffer layer 10d is made of GaN. When using the buffer layer, the lattice mismatch in crystal growth can be further reduced, so that the dislocation density can be further reduced and a higher effect than in the examples described above can be obtained.

Herein, a method for manufacturing the photocathode main body is explained.

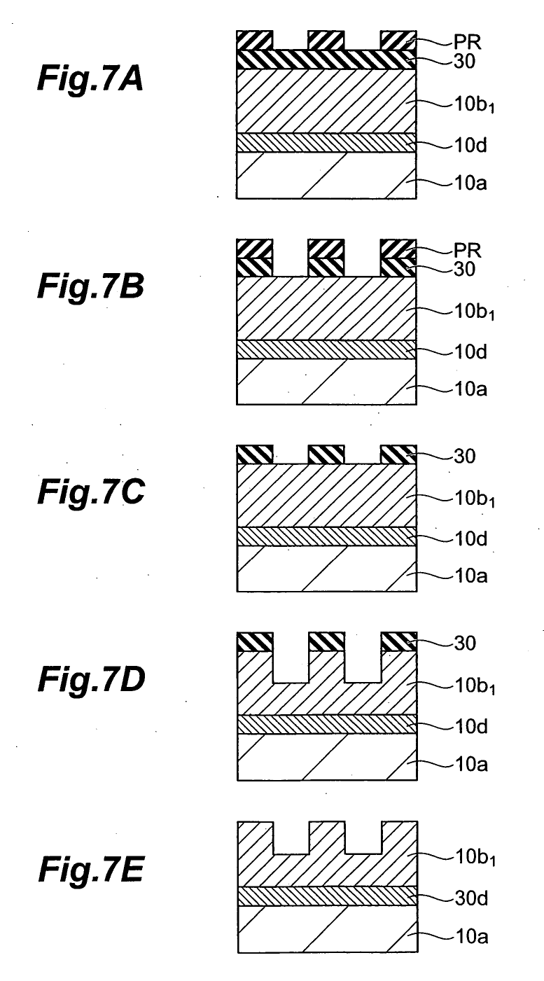

FIG. 7A, FIG. 7B, FIG. 7C, FIG. 7D, and FIG. 7E are drawings for explaining the method for manufacturing the substrate 10 of the photocathode main body shown in FIG. 6.

For the following crystal growth, metalorganic chemical vapor deposition (MOCVD) was used. As a Ga material, trimethyl gallium (TMGa) was used, and as an N material, ammonia (NH₃) was used. As a carrier gas, hydrogen and nitrogen were used.

For the base substrate 10a, sapphire (0001) was used. First, the base substrate 10a is introduced into an MOCVD growth system and then subjected to heat treatment for 5 minutes at 1050° C. in a hydrogen atmosphere to clean the substrate surface.

Thereafter, the substrate temperature is lowered to 475° C., and the buffer layer 10d of GaN is deposited to 25 nm on the base substrate 10a. The growing pressure was set to a normal pressure (1×10⁵ Pa), the TMGa feed rate was set to 46 μmol/min, and the NH₃ feed rate was set to 5 SLM.

After the GaN buffer layer 10d is deposited, the substrate is raised in temperature to 1075° C., and the foundation nitride compound semiconductor layer 10b₁ (GaN) is grown to approximately 4 μm on the buffer layer 10d. The growing pressure was set to a normal pressure (1×10⁵ Pa), the TMGa feed rate was set to 92 μmol/min, and the NH₃ feed rate was set to 8 SLM.

In this example, metalorganic chemical vapor deposition (MOCVD) was used for crystal growth, however, the invention is not limited to this, and molecular beam epitaxy (MBE), hydride vapor phase epitaxy (HVPE), or the like can also be used.

Next, to perform unevenness processing, the substrate having the nitride compound semiconductor layer 10b₁ grown on the sapphire (0001) is taken out of the growth system, and introduced into a plasma CVD system, and a mask 30 made of SiO₂ is deposited to 300 nm on the nitride compound semiconductor layer 10b₁. As the deposition conditions, a temperature of 400° C., a pressure of 93 Pa, a silane (SiH₄) flow rate of 10 SCCM, a nitrous oxide (N₂O) feed rate of 350 SCCM, and an argon (Ar) flow rate of 180 SMMC were set.

In this example, plasma CVD was used for deposition of the mask 30 made of SiO₂, however, the invention is not limited to this, and electron beam (EB) deposition, sputtering, or the like can be used.

After deposition of the mask 30, a photoresist mask PR patterned into periodic stripes is formed on the mask 30 by means of photolithography. The lengthwise direction of the stripes is the [11-20] direction of the sapphire substrate ([1-100] direction of the GaN crystal). The width of the stripes is 14 μm, and the period is 28 μm (FIG. 7A).

Next, the mask 30 is patterned. The mask 30 is etched by means of reactive ion etching (RIE) by using the photoresist PR patterned into periodic stripes as a sub mask. As etching conditions, an RF power of 150 W, a pressure of 5.3 Pa, a CF₄ flow rate of 45 SCCM, and an oxygen (O₂) flow rate of 5 SCCM are set and etching is continued until reaching the surface of the foundation nitride compound semiconductor layer 10b₁ (FIG. 7B).

Thereafter, the photoresist PR used as a mask was removed by an organic solvent and oxygen plasma treatment, whereby a periodic stripe pattern of SiO₂ was formed (FIG. 7C).

In this example, reactive ion etching was used for etching SiO₂, however, the invention is not limited to this, and a fluoride-based solution such as buffered hydrogen fluoride (BHF) can also be used.

Next, the foundation nitride compound semiconductor layer 10b₁ is etched. By using the formed periodic stripe pattern of SiO₂ as the mask 30, the foundation nitride compound semiconductor layer 10b₁ is etched by means of reactive ion etching (RIE). As etching conditions, an RF power of 280 W, a pressure of 4 Pa, a chlorine (Cl₂) flow rate of 20 SCCM, and a silicon tetrachloride (SiCl₄) flow rate of 5 SCCM are set, and the foundation nitride compound semiconductor layer 10b₁ is etched to a depth of approximately 2 μm from the surface (FIG. 7D).

After etching, SiO₂ used as the mask 30 is etched in a buffered hydrogen fluoride (BHF) solution (FIG. 7E).

In this example, reactive ion etching (RIE) was used for etching GaN, however, the invention is not limited to this, and reactive ion beam etching (RIBE), ICP dry etching, or the like can also be used.

As described above, after forming the substrate 10, the first nitride compound semiconductor layer 1 and the second nitride compound semiconductor layer 2 are grown.

First, the first nitride compound semiconductor layer (GaN) 1 shown in FIG. 6 is laterally embedded and grown. The substrate subjected to the unevenness processing is introduced into the MOCVD growth system again and subjected to heat treatment for 5 minutes at 1075° C. in a hydrogen and ammonia atmosphere to clean the substrate surface.

After cleaning the substrate surface, GaN is laterally embedded and grown at a substrate temperature of 1125° C. The grown film thickness corresponds to approximately 11 μm in the case of growth on a flat substrate. The growing pressure is 1×10⁴ Pa, the TMGa feed rate is 92 μmol/min, and the NH₃ feed rate is 3 SLM.

Thereafter, the second nitride compound semiconductor layer (GaN) 2 doped with magnesium (Mg) to become a light absorbing layer and an electron emitting layer of the photoelectric surface is grown to approximately 2.5 μm on the first nitride compound semiconductor layer 1. The growing pressure is a normal pressure (1×10⁵ Pa), the growing temperature is 1075° C., and the TMGa feed rate is 92 μmol/min, and the NH₃ feed rate is 8 SLM. As the Mg material, Bis (cyclopentadienyl) magnesium (Cp₂Mg) was used, and the Mg concentration was set to 3×10⁹ cm⁻³.

The photocathode main body is thus completed. After disposing of the photocathode main body in the vacuum container, an alkali layer 20 is formed on the exposed surface of the second nitride compound semiconductor layer 2, whereby a photocathode is completed.

The stripe period and depth can be arbitrarily set in certain ranges. Concerning the crystal structure, the doping and film thickness are not limited except that the second nitride compound semiconductor layer 2 to become a light absorbing and electron emitting layer at the uppermost layer is doped with Mg. The Mg concentration is preferably 3×10¹⁹ cm⁻³, however, it is not limited to this.

The crystal growing method and conditions and the process method and conditions shown in this example are only one example, and these are not limited as long as the target crystal growth and process are possible. In the unevenness processing shown in this example, GaN etching by using the SiO₂ mask was shown, however, the invention is not limited to this, and it is also possible that GaN is etched by using a resist or Ni as a mask.

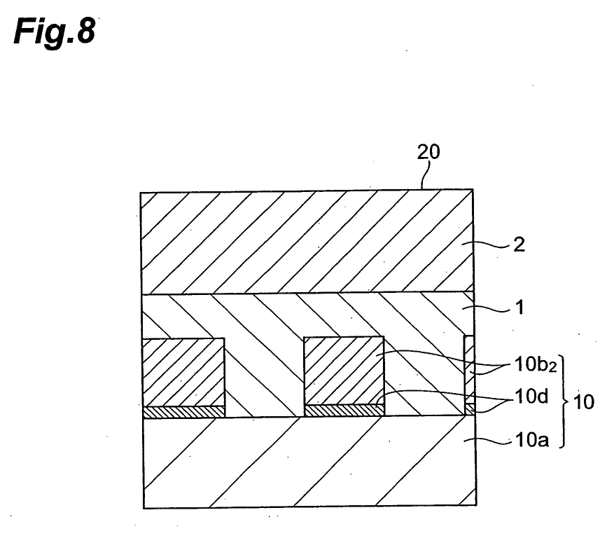

FIG. 8 is a longitudinal sectional view of the sixth photocathode main body to be applied to an electron tube. 101431 This photocathode main body further comprises, in addition to the photocathode main body of FIG. 3, a buffer layer 10d interposed between the base substrate 10a and the foundation nitride compound semiconductor layer 10b₂. The buffer layer 10d is made of GaN. As described above, by using the buffer layer, the dislocation defect density is reduced and the quantum efficiency is improved.

A method for manufacturing this photocathode main body is different only in the etching process of the foundation nitride compound semiconductor substrate in the photocathode shown in FIG. 6.

Namely, in place of the foundation nitride semiconductor layer 10b₁, the foundation nitride semiconductor layer 10b₂ is formed on the base substrate 10a via a buffer layer 10d, and on this foundation nitride semiconductor layer, a mask 30 and a photoresist pattern PR are formed, and by using the formed periodic stripe pattern of SiO₂ as the mask 30, the foundation nitride compound semiconductor layer 10b₂ (GaN) is etched by means of reactive ion etching (RIE). As etching conditions, an RF power of 280 W, a pressure of 4.0 Pa, a chlorine (Cl₂) flow rate of 20 SCCM, and a silicon tetrachloride (SiCl₄) flow rate of 5 SCCM are set and the foundation nitride semiconductor layer 10b₂ is etched by approximately 4 μm from the surface so as to reach the base substrate 10a. It is allowed that the base substrate 10a is etched together. After etching, SiO₂ used as the mask is etched in a buffered hydrogen fluoride (BHF) solution.

The residual process is the same as that of FIG. 6. The photocathode main body is thus completed. After disposing of the photocathode main body in the vacuum container, an alkali layer 20 is formed on the exposed surface of the second nitride compound semiconductor layer 2, whereby a photocathode is completed.

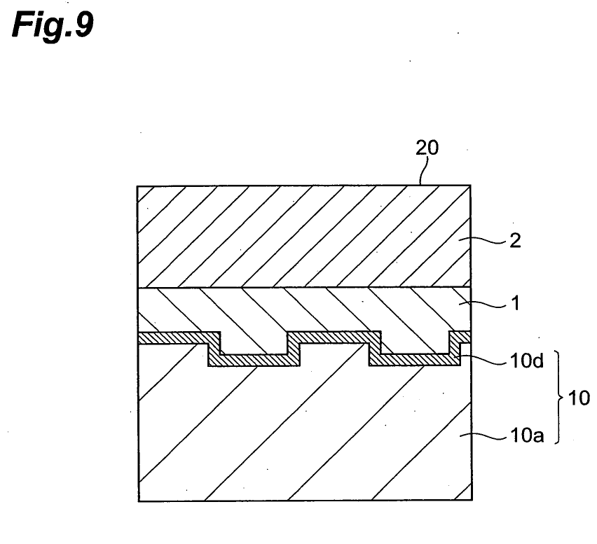

FIG. 9 is a longitudinal sectional view of the seventh photocathode main body to be applied to an electron tube.

This photocathode main body further comprises, in addition to the photocathode main body of FIG. 4, a buffer layer 10d interposed between the base substrate 10a and the first nitride compound semiconductor layer 1. The buffer layer 10d is made of GaN. As described above, by using the buffer layer, the dislocation defect density is reduced, and the quantum efficiency is improved.

A method for manufacturing this photocathode main body is explained. 101501 This manufacturing method is a result of adding the forming process of the buffer layer 10d to the process of FIG. 4.

Namely, on the base substrate 10a of sapphire (0001) etched into a stripe pattern, the first nitride compound semiconductor layer (GaN) 1 is formed. The base substrate 10a is introduced into an MOCVD growth system, and then subjected to heat treatment for 5 minutes at 1050° C. in a hydrogen atmosphere to clean the substrate surface.

Thereafter, the substrate temperature is lowered to 475° C., and a buffer layer 10d made of GaN is deposited to 25 nm on the substrate. The growing pressure was set to a normal pressure (1×10⁵ Pa), the TMGa feed rate was set to 46 μmol/min, and the NH₃ feed rate was set to 5 SLM.

The process after depositing the buffer layer 10d of GaN is the same as that of FIG. 4.

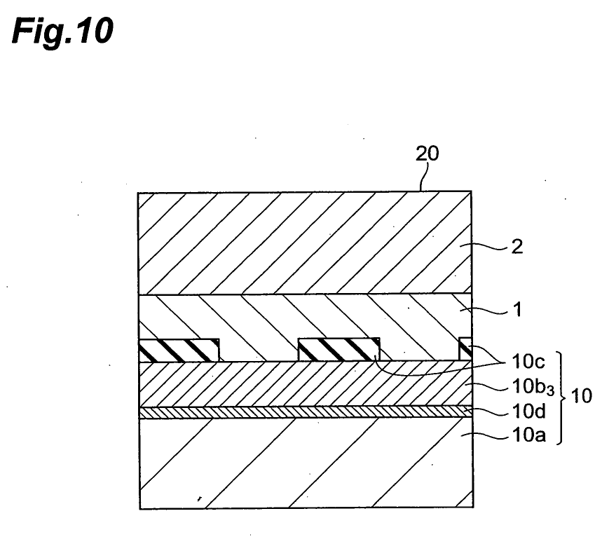

FIG. 10 is a longitudinal sectional view of the eighth photocathode main body to be applied to an electron tube.

This photocathode main body further comprises, in addition to the photocathode main body of FIG. 5, a buffer layer 10d interposed between the base substrate 10a and the foundation nitride compound semiconductor layer 10b₃. The buffer layer 10d is made of GaN. As described above, by using the buffer layer, the dislocation defect density is reduced, and the quantum efficiency is improved.

A method for manufacturing this photocathode main body is explained.

This manufacturing method is a result of adding a forming process of the buffer layer 10d to the process of FIG. 5. Namely, sapphire (0001) is used for the base substrate 10a, and the base substrate 10a is introduced into an MOCVD growth system and then subjected to heat treatment for 5 minutes at 1050° C. in a hydrogen atmosphere to clean the substrate surface. Thereafter, the substrate temperature is lowered to 475° C., and the GaN buffer layer 10d is deposited to 25 nm. The growing pressure was set to a normal pressure (1×10⁵ Pa), the TMGa feed rate was set to 46 μmol/min, and the NH₃ feed rate was set to 5 SLM.

After depositing the GaN buffer layer 10d, the temperature is raised to 1075° C., and the foundation nitride compound semiconductor layer (GaN) 10b₃ is grown to approximately 4 μm. The growing pressure is a normal pressure (1×10⁵ Pa), the TMGa feed rate is 92 μmol/min, and the NH₃ feed rate is 8 SLM.

The residual process is the same as that of FIG. 5.

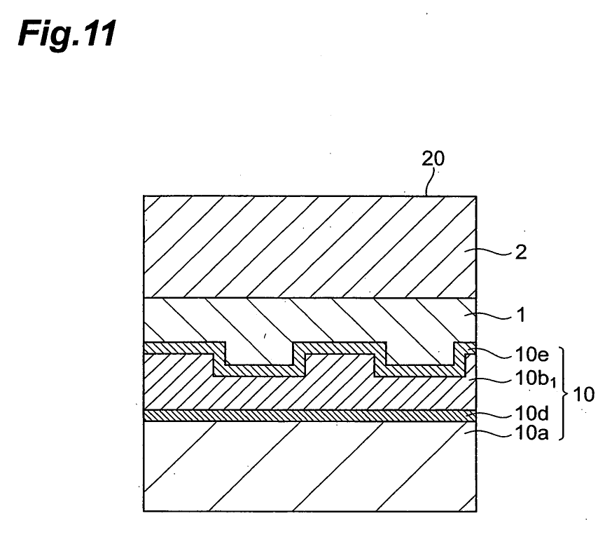

FIG. 11 is a longitudinal sectional view of the ninth photocathode main body to be applied to an electron tube.

This photocathode main body further comprises, in addition to the photocathode main body of FIG. 6, an AlN intermediate layer 10e interposed between the foundation nitride compound semiconductor layer 10b₁ and the first nitride compound semiconductor layer 1.

In this example, the base substrate 10a is made of sapphire, the buffer layer 10d is made of GaN, the foundation nitride compound semiconductor layer 10b₁ is made of GaN, and the first nitride compound semiconductor layer 1 and the second nitride compound semiconductor layer 2 are both made of AlGaN. In this example, the same effect as described above can be obtained. Particularly, the AlN intermediate layer 10e reduces the lattice mismatch between the foundation nitride compound semiconductor layer and the first nitride compound semiconductor layer 1, so that the dislocation density in the second nitride compound semiconductor layer 2 formed on the intermediate layer can be reduced and the quantum efficiency can be further improved.

A method for manufacturing this photocathode main body is described.

For crystal growth, metalorganic chemical vapor deposition (MOCVD) was used. As a Ga material, trimethyl gallium (TMGa) was used, as an Al material, trimethyl aluminum (TMAl) was used, and as an N material, ammonia (NH₃) was used. As a carrier gas, hydrogen and nitrogen were used.

For the substrate, sapphire (0001) was used. The substrate is introduced into an MOCVD growth system, and then subjected to heat treatment for 5 minutes at 1050° C. in a hydrogen atmosphere to clean the substrate surface.

Thereafter, the substrate temperature is lowered to 475° C., and the GaN buffer layer 10d is deposited to 25 nm. The growing pressure was set to a normal pressure (1×10⁵ Pa), the TMGa feed rate was set to 46 μmol/min, and the NH₃ feed rate was set to 5 SLM.

After depositing the GaN buffer layer 10d, the temperature is raised to 1075° C., and the foundation nitride compound semiconductor layer (GaN) 10b₁ is grown to approximately 4 μm. The growing pressure was set to a normal pressure (1×10⁵ Pa), the TMGa feed rate was set to 92 μmol/min, and the NH₃ feed rate was set to 8 SLM.

In this example, metalorganic chemical vapor deposition (MOCVD) was used for crystal growth. The invention is not limited to this, and molecular beam epitaxy (MBE), hydride vapor phase epitaxy (HVPE), or the like can also be used.

The substrate including the buffer layer 10d and the foundation nitride compound semiconductor layer (GaN) 10b₁ grown on sapphire (0001) is taken out of the growth system and introduced into a plasma CVD system, and a mask made of SiO₂ is deposited to 300 nm. As deposition conditions, a temperature of 400° C., a pressure of 93 Pa, a silane (SiH₄) flow rate of 10 SCCM, a nitrous oxide (N₂O) feed rate of 350 SCCM, and an argon (Ar) flow rate of 180 SCCM) were set.

In this example, plasma CVD was used for deposition of the mask of SiO₂, however, the invention is not limited to this, and electron beam (EB) deposition, sputtering, or the like can also be used.

After deposition of the mask of SiO₂, a photoresist mask patterned into periodic stripes is formed by means of photolithography. The stripe direction is the [11-20] direction of the sapphire substrate ([1-100] direction of the GaN crystal). The stripe width is 14 μm and the period is 28 μm.

By using the resist patterned into periodic stripes as a sub mask, the mask of SiO₂ is etched by means of reactive ion etching (RIE). As etching conditions, an RF power of 150 W, a pressure of 5.3 Pa, a CF₄ flow rate of 45 SCCM, and an oxygen (O₂) flow rate of 5 SCCM are set and etching is continued until reaching the surface of the foundation nitride compound semiconductor layer 10b₁. Thereafter, the resist used as a mask is removed by an organic solvent and oxygen plasma treatment to form a periodic stripe pattern of SiO₂.

In this example, reactive ion etching was used for etching SiO₂, however, the invention is not limited to this, and a fluoride-based solution such as buffered hydrogen fluoride (BHF) can also be used.

The foundation nitride compound semiconductor layer 10b₁ is reactive-ion-etched (RIE) by using the formed periodic stripe pattern of SiO₂ as a mask. As etching conditions, an RF power of 280 W, a pressure of 4.0 Pa, a chlorine (Cl₂) flow rate of 20 SCCM, and a silicon tetrachloride (SiCl₄) flow rate of 5 SCCM are set and the foundation nitride compound semiconductor layer 10b₁ is etched to approximately 2 μm from the surface. After etching, SiO₂ used as a mask is etched in a buffered hydrogen fluoride (BHF) solution.

In this example, reactive ion etching (RIE) was used for etching GaN, however, the invention is not limited to this, and reactive ion beam etching (RIBE), ICP dry etching, or the like can also be used.

The substrate subjected to unevenness processing is introduced into the MOCVD growth system again, and subjected to heat treatment for 5 minutes at 1075° C. in a hydrogen and ammonia atmosphere to clean the substrate surface.

After cleaning the substrate surface, the substrate temperature is lowered to 550° C., and an AlN intermediate layer 10e is deposited to 10 nm. The growing pressure was set to a normal pressure (1×10⁵ Pa), the TMAl feed rate was set to 46 μmol/min, and the NH₃ feed rate was set to 5 SLM.

After depositing the AlN intermediate layer, the substrate temperature is raised to 1125° C., and the first nitride compound semiconductor layer 1 made of AlGaN (composition ratio of Al: 30%) is laterally embedded and grown. The growing pressure is 1×10⁴ Pa, the total feed rate of TMGa and TMAl is 92 μmol/min, and the NH₃ feed rate is 3 SLM.

Thereafter, the second nitride compound semiconductor layer 2 made of AlGaN (composition ratio of Al: 30%) doped with magnesium (Mg) to become a light absorbing layer and an electron emitting layer of the photoelectric surface is grown on the first nitride compound semiconductor layer. The growing pressure is 4.0×10⁴ Pa, the growing temperature is 1075° C., the total feed rate of TMGa and TMAl is 92 μmol/min, and the NH₃ feed rate is 3 SLM. As the Mg material, Bis (cyclopentadienyl) magnesium (Cp₂Mg) was used and the Mg concentration was set to 3×10¹⁹ cm⁻³.

The stripe period and depth can be arbitrarily set in certain ranges. Concerning the crystal structure, the doping and film thickness are not always limited except that the light absorbing and electron emitting layer of the uppermost layer is doped with Mg. The Mg doping concentration is preferably 3×10¹⁹ cm⁻³, however, it is not limited to this.

The crystal growing method and conditions and the process method and conditions shown in this example are only one example, and these are not limited as long as the target crystal growth and process are possible.

In the unevenness processing shown in the example, GaN etching by using an SiO₂ mask was shown, however, the invention is not limited to this, and GaN etching by using a resist or Ni as a mask is also possible.

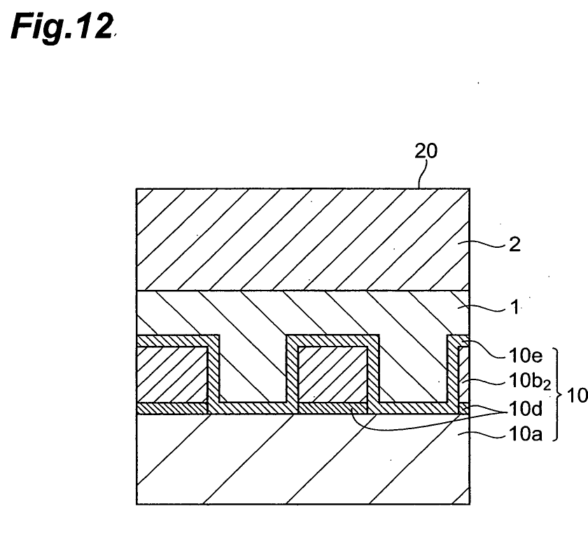

FIG. 12 is a longitudinal sectional view of the tenth photocathode main body to be applied to an electron tube.

This photocathode main body further comprises, in addition to the photocathode main body of FIG. 8, an AlN intermediate layer 10e interposed between the exposed surfaces of the base substrate 10a and the foundation nitride compound semiconductor layer 10b₂ and the first nitride compound semiconductor layer 1.

In this example, the base substrate 10a is made of sapphire, the buffer layer 10d is made of GaN, the foundation nitride compound semiconductor layer 10b₂ is made of GaN, and the first nitride compound semiconductor layer 1 and the second nitride compound semiconductor layer 2 are both made of AlGaN.

In this example, the same effect as described above is obtained. Particularly, the AlN intermediate layer 10e reduces the lattice mismatch between the foundation nitride compound semiconductor layer and the first nitride compound semiconductor layer 1, so that the dislocation density in the second nitride compound semiconductor layer 2 formed on the AlN intermediate layer is reduced and the quantum efficiency is further improved.

A method for manufacturing this photocathode main body is explained.

This manufacturing method is a result of adding a forming process of the AlN intermediate layer 10e to the process of FIG. 8. The method for forming the first and second nitride compound semiconductor layers 1 and 2 made of AlGaN is the same as described in FIG. 11.

Namely, when the foundation nitride compound semiconductor layer 10b₂ made of GaN is reactive-ion-etched (RIE) by using a periodic stripe pattern of SiO₂ as a mask, as etching conditions, an RF power of 280 W, a pressure of 4.0 Pa, a chlorine (Cl₂) flow rate of 20 SCCM, and a silicon tetrachloride (SiCl₄) flow rate of 5 SCCM are set, and the foundation nitride compound semiconductor layer 10b₂ is etched by 4 μm from the surface so as to reach the substrate. The substrate can also be etched together. After etching, SiO₂ used as a mask is etched in a buffered hydrogen fluoride (BHF) solution.

Thereafter, in the same manner as in the process of FIG. 11, the AlN intermediate layer 10e and the first and second nitride compound semiconductor layers 1 and 2 made of AlGaN are formed in order.

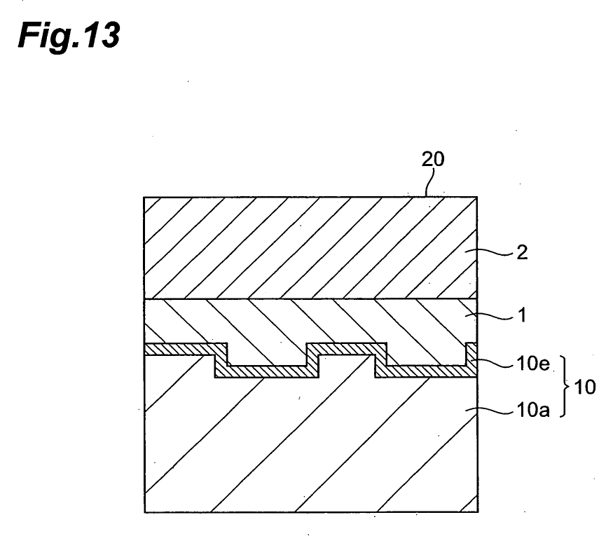

FIG. 13 is a longitudinal sectional view of the eleventh photocathode main body to be applied to an electron tube.

This photocathode main body further comprises, in addition to the photocathode main body of FIG. 9, an AlN intermediate layer 10e interposed between the base substrate 10a and the first nitride compound semiconductor layer 1.

In this example, the base substrate 10a is made of sapphire, and the first nitride compound semiconductor layer 1 and the second nitride compound semiconductor layer 2 are both made of AlGaN.

In this example, the same effect as described above is obtained. Particularly, the AlN intermediate layer 10e reduces the lattice mismatch between the foundation nitride compound semiconductor layer and the first nitride compound semiconductor layer 1, so that the dislocation density in the second nitride compound semiconductor layer 2 formed on the AlN intermediate layer is reduced and the quantum efficiency can be further improved.

A method for manufacturing this photocathode main body is explained.

This manufacturing method is a result of adding a forming process of the AlN intermediate layer 10e in place of the buffer layer 10d to the process of FIG. 9.

The base substrate 10a made of sapphire (0001) subjected to unevenness processing in the same manner as in FIG. 9 is introduced into an MOCVD growth system and then subjected to heat treatment for 5 minutes at 1050° C. in a hydrogen atmosphere to clean the substrate surface.

Thereafter, the substrate temperature is lowered to 450° C., and the AlN intermediate layer (buffer layer) 10e is deposited to 50 nm. The growing pressure was set to a normal pressure (1×10⁴ Pa), the TMAl feed rate was set to 46 μmol/min, and the NH₃ feed rate was set to 5 SLM.

After depositing the AlN intermediate layer 10e, the first nitride compound semiconductor layer 1 made of AlGaN (composition ratio of Al: 30%) is laterally embedded and grown at a substrate temperature of 1125° C. The growing pressure is 1×10⁴ Pa, the total feed rate of TMGa and TMAl is 92 μmol/min, and the NH₃ feed rate is 3 SLM.

Thereafter, the second nitride compound semiconductor layer 2 made of AlGaN (composition ratio of Al: 30%) doped with magnesium (Mg) to become a light absorbing layer and an electron emitting layer of the photoelectric surface is grown. The growing pressure is 4.0×10⁴ Pa, the growing temperature is 1075° C., the total feed rate of TMGa and TMAl is 92 μmol/min, and the NH₃ feed rate is 3 SLM. As the Mg material, Bis (cyclopentadienyl) magnesium (Cp₂Mg) was used and the Mg concentration was set to 3×10¹⁹ cm⁻³.

In this example, metalorganic chemical vapor deposition (MOCVD) was used for crystal growth. The invention is not limited to this, and molecular beam epitaxy (MBE), hydride vapor phase epitaxy (HVPE), or the like can also be used.

The stripe period and depth can be arbitrarily set in certain ranges. Concerning the crystal structure, the doping and film thickness are not always limited except that the uppermost light absorbing and electron emitting layer is doped with Mg. The Mg doping concentration is preferably 3×10¹⁹ cm⁻³, however, it is not limited to this.

The crystal growing method and conditions and the process method and conditions shown in this example are only one example, and these are not limited as long as the target crystal growth and process are possible.

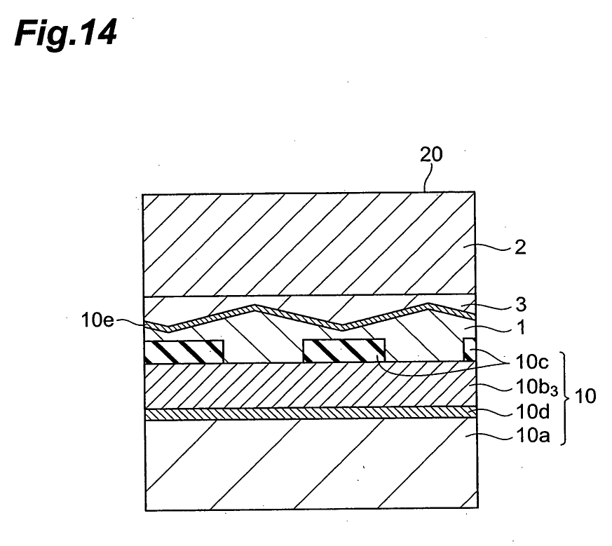

FIG. 14 is a longitudinal sectional view of the twelfth photocathode main body to be applied to an electron tube.

This photocathode main body comprises, in addition to the photocathode main body of FIG. 10, an intermediate embedded layer 3 interposed between the first nitride compound semiconductor layer 1 and the second nitride compound semiconductor layer 2.

In this example, the base substrate 10a is made of sapphire, the buffer layer 10d is made of GaN, the foundation nitride compound semiconductor layer 10b₃ is made of GaN, the mask layer 10c is made of SiO₂, the first nitride compound semiconductor layer 1 is made of GaN, the second nitride compound semiconductor layer 2 is made of AlGaN, and the intermediate embedded layer 3 is made of AlGaN.

In this example, the same effect as described above can be obtained. Particularly, the intermediate embedded layer 3 reduces the lattice mismatch between the first nitride compound semiconductor layer 1 and the second nitride compound semiconductor layer 2, so that the dislocation density in the second nitride compound semiconductor layer 2 formed on the intermediate embedded layer is reduced, and the quantum efficiency can be further improved.

A method for manufacturing this photocathode main body is explained.

For crystal growth, metalorganic chemical vapor deposition (MOCVD) was used. As a Ga material, trimethyl gallium (TMGa) was used, and as an N material, ammonia (NH₃) was used. As a carrier gas, hydrogen and nitrogen were used.

For the base substrate 10a, sapphire (0001) was used. The base substrate 10a is introduced into an MOCVD growth system and then subjected to heat treatment for 5 minutes at 1050° C. in a hydrogen atmosphere to clean the substrate surface.

Thereafter, the substrate temperature is lowered to 475° C., and the GaN buffer layer 10d is deposited to 25 nm. The growing pressure was set to a normal pressure (1×10⁵ Pa), the TMGa feed rate was set to 46 μmol/min, and the NH₃ feed rate was set to 5 SLM.

After depositing the GaN buffer layer 10d, the temperature is raised to 1075° C., and the foundation nitride compound semiconductor layer 10b₃ made of GaN is grown to approximately 4 μm. The growing pressure was set to a normal pressure (1×10⁵ Pa), the TMGa feed rate was set to 92 μmol/min, and the NH₃ feed rate was set to 8 SLM.

In this example, the metalorganic chemical vapor deposition (MOCVD) was used for crystal growth, however, the invention is not limited to this, and molecular beam epitaxy (MBE), hydride vapor phase epitaxy (HVPE), or the like can also be used.

Next, the substrate including the foundation nitride compound semiconductor layer 10b₃ grown on sapphire (0001) is taken out of the growth system and introduced into a plasma CVD system, and a mask of SiO₂ is deposited to 300 nm. As deposition conditions, a temperature of 400° C., a pressure of 93 Pa, a silane (SiH₄) flow rate of 10 SCCM, a nitrous oxide (N₂O) feed rate of 350 SCCM, and an argon (Ar) flow rate of 180 SCCM were set.

In this example, plasma CVD was used for deposition of the mask 30, however, the invention is not limited to this, and electron beam (EB) deposition, sputtering, or the like can be used.

After deposition of the mask of SiO₂, a photoresist mask patterned into periodic stripes is formed by means of photolithography. The stripe direction is the [11-20) direction of the sapphire substrate ([1-100 direction of the GaN crystal). The width of the stripes is 4 μm, and the period is 14 μm.

The mask of SiO₂ is etched by means of reactive ion etching (RIE) by using the resist patterned into periodic stripes as a sub mask. As etching conditions, an RF power is set to 150 W, a pressure is set to 5.3 Pa, a CF₄ flow rate is set to 45 SCCM, and an oxygen (O₂) flow rate is set to 5 SCCM, and etching is performed until reaching the surface of the foundation nitride compound semiconductor layer 10b₃. Thereafter, the resist used as a sub mask was removed by an organic solvent and oxygen plasma treatment, whereby a periodic stripe pattern of SiO₂ was formed.

In this example, reactive ion etching was used for etching SiO₂, however, the invention is not limited to this, and a fluoride-based solution such as buffered hydrogen fluoride (BHF) can also be used.

The substrate having the formed SiO₂ stripes is introduced into the MOCVD growth system again and subjected to heat treatment for 5 minutes at 1075° C. in a hydrogen and ammonia atmosphere to clean the substrate surface.

After cleaning the substrate surface, the first nitride compound semiconductor layer 1 made of GaN is laterally embedded and grown. The substrate temperature is 1025° C. and the growing pressure is 6.7×10⁴ Pa, and growth is made while forming facets (for example, the [11-22] surface and [11-20] surface). The TMGa feed rate in this case is 92 μmol/min, and the NH₃ feed rate is 3 SLM.

Thereafter, the substrate temperature is lowered to 550° C., and the AlN intermediate layer 10e is deposited to 10 nm. The growing pressure was set to a normal pressure (1×10⁵ Pa), the TMAl feed rate was set to 46 μmol/min, and the NH₃ feed rate was set to 5 SLM.

After depositing the AlN intermediate layer 10e, the substrate temperature is raised to 1125° C., and the intermediate embedding layer 3 made of AlGaN (composition ratio of Al: 30%) is laterally embedded and grown on the AlN intermediate layer 10e. The growing pressure is 1×10⁴ Pa, the total feed rate of TMGa and TMAl is 92 μmol/min, and the NH₃ feed rate is 3 SLM. The forming process of AlN intermediate layer 10e can be omitted.

Thereafter, the second nitride compound semiconductor layer 2 made of AlGaN (composition ratio of Al: 30%) doped with magnesium (Mg) to become a light absorbing layer and an electron emitting layer of the photoelectric surface is grown. The growing pressure is 4.0×10⁴ Pa, the growing temperature is 1075° C., the total feed rate of TMGa and TMAl is 92 μmol/min, and the NH₃ feed rate is 3 SLM. As the Mg material, Bis (cyclopentadienyl) magnesium (Cp₂Mg) was used and the Mg concentration was set to 3×10¹⁹ cm⁻³.

The stripe period can be arbitrarily set in a certain range. Concerning the crystal structure, the doping and film thickness are not always limited except that the light absorbing and electron emitting layer of the uppermost layer is doped, with Mg. The Mg doping concentration is preferably 3×10¹⁹ cm⁻³, however, it is not limited to this.

The crystal growing method and conditions and the process method and conditions shown in this example are only one example, and these are not limited as long as the target crystal growth and process are possible.

In all examples described above, there is no problem with inserting a layer that has a function of reducing distortion of the buffer layer or the intermediate layer or other functions to the interface between the substrate and the nitride semiconductor and the interface between the nitride semiconductors. The mask is not limited to SiO₂ and SiN. In the above-described embedding growth, a gap is allowed. Furthermore, an AlGaN crack preventive layer may be interposed between the AlGaN embedded layer and the GaN layer in addition to the AlN intermediate layer grown at a low temperature.

The material of the substrate 10 may contain at least one kind selected from a group consisting of sapphire, SiC, Si, GaN, AlN, and AlGaN.

Next, an effect in the case where the substrate 10 having the above-described uneven surface is used is further explained.

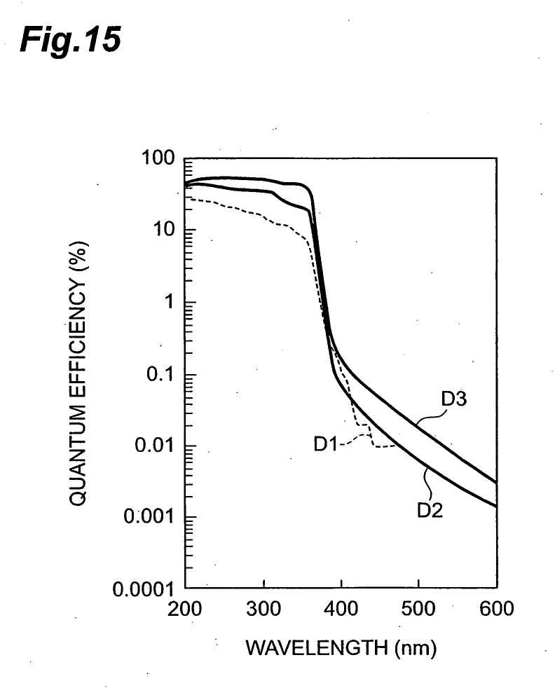

FIG. 15 is a graph showing the relationship between wavelength (nm) of light entering the electron tube and quantum efficiency (%).

The data D1 indicates characteristic data of the photocathode made by Ms. Shahedipour, the data D2 indicates characteristic data of a photocathode without unevenness, and the data D3 indicates characteristic data of the photocathode (FIG. 6) using the substrate having an uneven surface of the embodiment.

As seen in this graph, the quantum efficiency of the data D3 is almost twice the data D2 in the ultraviolet range of wavelength, corresponding to 5 times the data D1. The data D3 in the ultraviolet range of wavelength (200 nm to 365 nm) showing this spectral sensitivity is flat. The average of the quantum efficiency in this range of wavelength is 60% or more, and errors are within ±10%. This is the world's first result. The quantum efficiency at a wavelength of 280 nm is also 50% or more.

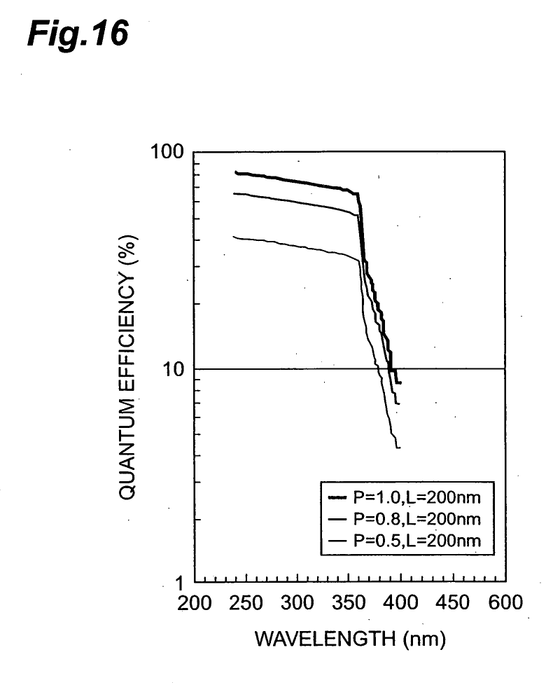

FIG. 16 is a graph showing the relationship between wavelength (nm) and quantum efficiency (%) when the electron escape probability is changed. This graph shows calculated values.

When the electron diffusion length L is fixed at 200 nm and the electron escape probability P is set to 1.0, 0.8, and 0.5, it is understood that the higher the escape probability P the higher the quantum efficiency. As the escape probability P becomes higher, the quantum efficiency increases with an even rate at any wavelength.

The quantum efficiency Y (hγ) at a wavelength hγ can be calculated as follows by using an electron diffusion length L(hγ) at the wavelength hγ, an absorption coefficient α(hγ) at the wavelength hγ, and an electron escape probability P(hγ) at the wavelength hγ. 280 nm is used as a wavelength standard. α is set to 1.68×10⁵ cm⁻¹.
Y(hγ)=P(hγ)/(1+1/L(hγ)+α(hγ)))

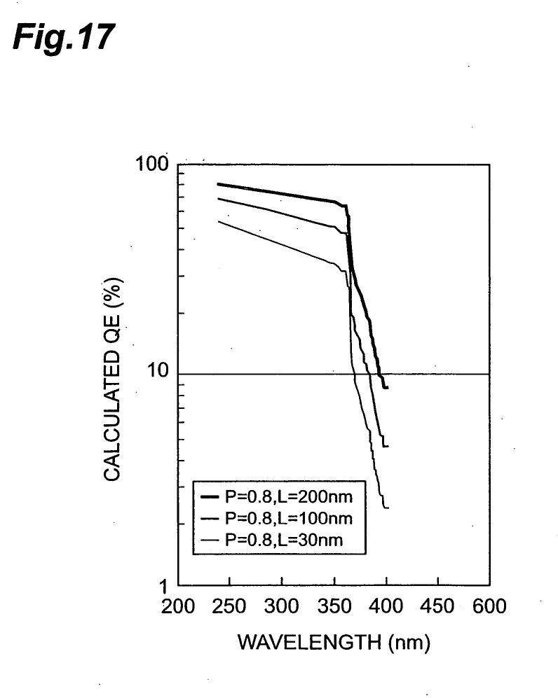

FIG. 17 is a graph showing the relationship between wavelength (nm) and quantum efficiency (%) when the difflusion length is changed. This graph shows calculated values.

The calculation is performed by setting L=200 nm, 100 nm, and 30 nm, and a probability P=0.8. As the diffusion length becomes longer, the quantum efficiency becomes higher, however, this effect differs depending on the wavelength. The effect becomes higher as the wavelength becomes longer. By lengthening the diffusion length, the spectral sensitivity characteristics can be made more flat.

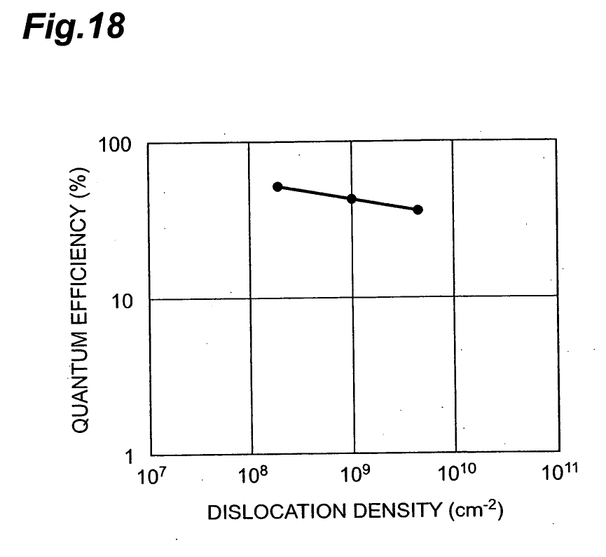

FIG. 18 is a graph showing the relationship between dislocation density (cm⁻²) of GaN and quantum efficiency (%).

It is understood from this graph that the lower the dislocation density, the higher the quantum efficiency (%). Namely, in the photocathode of the invention, the dislocation density is lowered, the diffusion length is longer than conventional, and high quantum efficiency that is flat with respect to wavelengths is obtained.

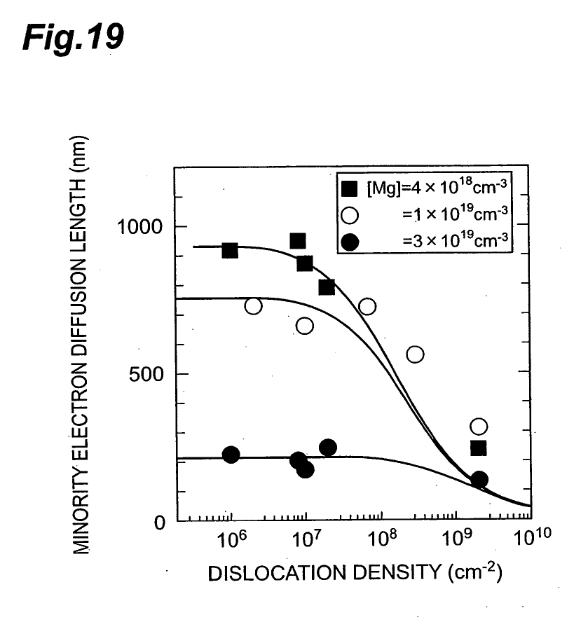

FIG. 19 is a graph showing the relationship between dislocation density (cm⁻²) and minority electron diffusion length (nm).

The second nitride compound semiconductor layer 2 is doped with Mg, however, it is understood that the lower the dislocation density, the longer the minority electron diffusion length (nm). This effect becomes greater, in particular, when the Mg concentration is low, and when the Mg concentration is 4×10¹⁸ cm⁻³, the diffusion length reaches 900 nm at a dislocation density of 10⁶ cm⁻². Namely, even when the Mg concentration is 4×10¹⁸ cm⁻³ or more, the electron diffusion length is long, and the quantum efficiency increases.

What is claimed is:

1. An electron tube comprising:
a vacuum container;
a photocathode disposed inside the vacuum container, including:
a substrate having an uneven surface,
first nitride compound semiconductor layer grown in depressions and on projections of the uneven surface of the substrate, and
a second nitride compound semiconductor layer that is grown on the first nitride compound semiconductor layer and has an impurity concentration higher than that of the first nitride compound semiconductor layer; and
an anode that is disposed inside the vacuum container and collects electrons emitted from the photocathode.

2. The electron tube according to claim 1, wherein
the substrate includes:
a base substrate; and
a foundation nitride compound semiconductor layer that is formed on the base substrate and has the uneven surface.

3. The electron tube according to claim 1, wherein the substrate includes:
a base substrate; and
a foundation nitride compound semiconductor layer that is formed on the base substrate and forms the uneven surface in conjunction with an exposed surface of the base substrate.

4. The electron tube according to claim 1, wherein
the substrate consists of only a base substrate that is made of a single material and has the uneven surface.

5. The electron tube according to claim 1, wherein
the substrate includes:
a base substrate;
a foundation nitride compound semiconductor layer formed on the base substrate; and
a stripe-patterned mask layer formed on the foundation nitride compound semiconductor layer, and
the surface of the mask layer forms the uneven surface in conjunction with an exposed surface of the foundation nitride compound semiconductor layer.

6. The electron tube according to claim 2, 3 or 5, further comprising:
a buffer layer interposed between the base substrate and the foundation nitride compound semiconductor layer.

7. The electron tube according to claim 4, further comprising:
a buffer layer interposed between the base substrate and the first nitride compound semiconductor layer.

8. The electron tube according to claim 1, wherein
the first and second nitride compound semiconductor layers are both made of GaN.

9. The electron tube according to claim 1, wherein
the first and second nitride compound semiconductor layers are both made of AlGaN.

10. The electron tube according to claim 2, wherein
the first and second nitride compound semiconductor layers are both made of AlGaN, and
the electron tube further comprises an AlN intermediate layer interposed between the foundation nitride compound semiconductor layer and the first nitride compound semiconductor layer.

11. The electron tube according to claim 3, wherein
the first and second nitride compound semiconductor layers are both made of AlGaN, and
the electron tube further comprises an AlN intermediate layer interposed between exposed surfaces of the base substrate and the foundation nitride compound semiconductor layer and the first nitride compound semiconductor layer.

12. The electron tube according to claim 4, wherein
the first and second nitride compound semiconductor layers are both made of AlGaN, and
the electron tube further comprises an AlN intermediate layer interposed between the base substrate and the first nitride compound semiconductor layer.

13. The electron tube according to claim 1, wherein
the electron tube comprises an intermediate embedded layer interposed between the first nitride compound semiconductor layer and the second nitride compound semiconductor layer, wherein
the first nitride compound semiconductor layer is made of GaN,
the second nitride compound semiconductor layer is made of AlGaN, and
the intermediate embedded layer is made of AlGaN.

14. The electron tube according to claim 13, wherein
an AlN intermediate layer is arranged between said first nitride compound semiconductor layer and said intermediate embedded layer.

15. The electron tube according to claim 1, wherein
the substrate material contains at least one kind selected from a group consisting of sapphire, SiC, Si, GaN, AlN, and AlGaN.
